(19) United States
(12) Patent Application Publication
(10) Pub. No.: US 2014/0117426 A1
(43) Pub. Date: May 1, 2014

(54) SEMICONDUCTOR DEVICE AND METHOD FOR FABRICATING THE SAME

(71) Applicants: Soon Cho, Hwaseong-si (KR); Chang-Seop Yoon, Yangsan-si (KR)

(72) Inventors: Soon Cho, Hwaseong-si (KR); Chang-Seop Yoon, Yangsan-si (KR)

(21) Appl. No.: 14/034,787

(22) Filed: Sep. 24, 2013

(30) Foreign Application Priority Data
Oct. 25, 2012 (KR) 10-2012-0119216

(51) Int. Cl. H01L 29/78; H01L 21/308

(52) U.S. Cl. CPC H01L 29/785; H01L 21/308
USPC 257/288; 438/706; 438/689

(57) ABSTRACT

A semiconductor device and a method for fabricating the same are provided. The semiconductor device comprising a substrate, a first fin formed on the substrate, and an isolation film formed on the substrate and coming in contact with a part of the first fin, wherein the first fin includes a first region that is in contact with the isolation film, a second region that is in non-contact with the isolation film, and a boundary line between the first region and the second region, the first region has a slope that is at right angles with respect to the boundary line, and the second region has a slope that is an acute angle with respect to the boundary line.

### CROSS-REFERENCE TO RELATED APPLICATIONS

This U.S. non-provisional patent application claims priority under 35 U.S.C. §119 to Korean Patent Application No. 10-2012-0119216, filed on Oct. 25, 2012 in the Korean Intellectual Property Office, the disclosure of which is hereby incorporated by reference in its entirety.

### BACKGROUND

Embodiments of the present invention relate to a semiconductor device and a method for fabricating the same.

To heighten the density of a semiconductor device, a multi-gate transistor has been proposed, in which a fin-type silicon body is formed on a substrate and a gate is formed on a surface of the silicon body.

Since the multi-gate transistor uses a three-dimensional (3D) channel, scaling can be performed. Further, a current control capability can be improved even without increasing a gate length of the multi-gate transistor. In addition, a short channel effect (SCE) that an electric potential of a channel region is affected by a drain voltage can be effectively suppressed.

### SUMMARY

Embodiments of the present invention describe a semiconductor device that can improve reliability by increasing the density of fins and reducing leakage current at the same time, using hybrid fins in which vertical fins and tapered fins are combined with each other.

Embodiments of the present invention also provide a method for fabricating the semiconductor device.

According to some embodiments of the present invention, a semiconductor device comprises a substrate, a first fin formed on the substrate, and an isolation film formed on the substrate and coming in contact with a part of the first fin, wherein the first fin includes a first region that is in contact with the isolation film, a second region that is in non-contact with the isolation film, and a boundary line between the first region and the second region, the first region has a slope that is at right angles with respect to the boundary line, and the second region has a slope that is an acute angle with respect to the boundary line.

According to some embodiments of the present invention, a method for fabricating a semiconductor device comprises forming a dummy fin having a slope that is at right angles, forming a pre-isolation film which surrounds a circumference of the dummy fin and exposes an upper surface of the dummy fin, and forming a fin, which includes a first region having a slope that is at right angles, a second region having an acute angle, and a boundary line between the first region and the second region, by etching the dummy fin and the pre-isolation film, and forming an isolation film that is in contact with the first region.

According to some embodiments, a method for fabricating a semiconductor device comprises etching a substrate with a first etchant and a fin mask pattern to form a fin extending in a vertical direction on the substrate and removing the fin mask pattern. The method also comprises forming a pre-isolation film that surrounds the fin and exposes an upper surface of the fin and simultaneously etching the pre-isolation film and the fin with a second etchant to form an isolation film in contact with a lower portion of the fin and expose a curved upper portion of the fin. The horizontal etch rate of the fin with the second etchant is greater than the horizontal etch rate of the fin with the first etchant.

Additional advantages, subjects, and features of the invention will be set forth in part in the description which follows and in part will become apparent to those having ordinary skill in the art upon examination of the following or may be learned from practice of the invention.

### BRIEF DESCRIPTION OF THE DRAWINGS

The above and other objects, features and advantages of the present invention will be more apparent from the following detailed description taken in conjunction with the accompanying drawings, in which:

FIG. 1 is a view explaining a semiconductor device according to an embodiment of the present invention;

FIG. 2 is an enlarged view of a portion X in FIG. 1;

FIG. 3 is a view explaining a semiconductor device according to another embodiment of the present invention,

FIG. 4 is an enlarged view of a portion Y in FIG. 3;

FIG. 5 is a view explaining a semiconductor device according to still another embodiment of the present invention;

FIG. 6 is a cross-sectional view taken along line AA in FIG. 5;

FIG. 7 is a cross-sectional view taken along line BB in FIG. 5;

FIGS. 8 to 23 are views explaining intermediate steps of a method for fabricating a semiconductor device according to an embodiment of the present invention;

FIG. 24 is a block diagram of an electronic system including a semiconductor device according to some embodiments of the present invention; and

FIGS. 25 and 26 are exemplary views of a semiconductor system to which the semiconductor device according to some embodiments of the present invention can be applied.

### DETAILED DESCRIPTION

The present invention will now be described more fully hereinafter with reference to the accompanying drawings, in which preferred embodiments of the invention are shown. This invention may, however, be embodied in different forms and should not be construed as limited to the embodiments set forth herein. Rather, these embodiments are provided so that this disclosure will be thorough and complete, and will fully convey the scope of the invention to those skilled in the art. The same reference numbers indicate the same components throughout the specification. In the attached figures, the thickness of layers and regions may be exaggerated for clarity.

It will be understood that when an element or layer is referred to as being “connected to,” or “coupled to” another element or layer, it can be directly connected to or coupled to another element or layer or intervening elements or layers may be present. In contrast, when an element is referred to as being “directly connected to” or “directly coupled to” another element or layer, there are no intervening elements or layers present. Like numbers refer to like elements throughout. As used herein, the term “and/or” includes any and all combinations of one or more of the associated listed items.

It will also be understood that when a layer is referred to as being “on” another layer or substrate, it can be directly on the other layer or substrate, or intervening layers may also be present. In contrast, when an element is referred to as being “directly on” another element, there are no intervening elements present.

It will be understood that, although the terms first, second, etc. may be used herein to describe various elements, these elements should not be limited by these terms. These terms are only used to distinguish one element from another element. Thus, for example, a first element, a first component or a first section discussed below could be termed a second element, a second component or a second section without departing from the teachings of the present invention.

The use of the terms “a” and “an” and “the” and similar referents in the context of describing the invention (especially in the context of the following claims) are to be construed to cover both the singular and the plural, unless otherwise indicated herein or clearly contradicted by context. The terms “comprising,” “having,” “including,” and “containing” are to be construed as open-ended terms (i.e., meaning “including, but not limited to,”) unless otherwise noted.

The present invention will be described with reference to perspective views, cross-sectional views, and/or plan views, in which preferred embodiments of the invention are shown. Thus, the profile of an exemplary view may be modified according to manufacturing techniques and/or allowances. That is, the embodiments of the invention are not intended to limit the scope of the present invention but cover all changes and modifications that can be caused due to a change in manufacturing process. Thus, regions shown in the drawings are illustrated in schematic form and the shapes of the regions are presented simply by way of illustration and not as a limitation.

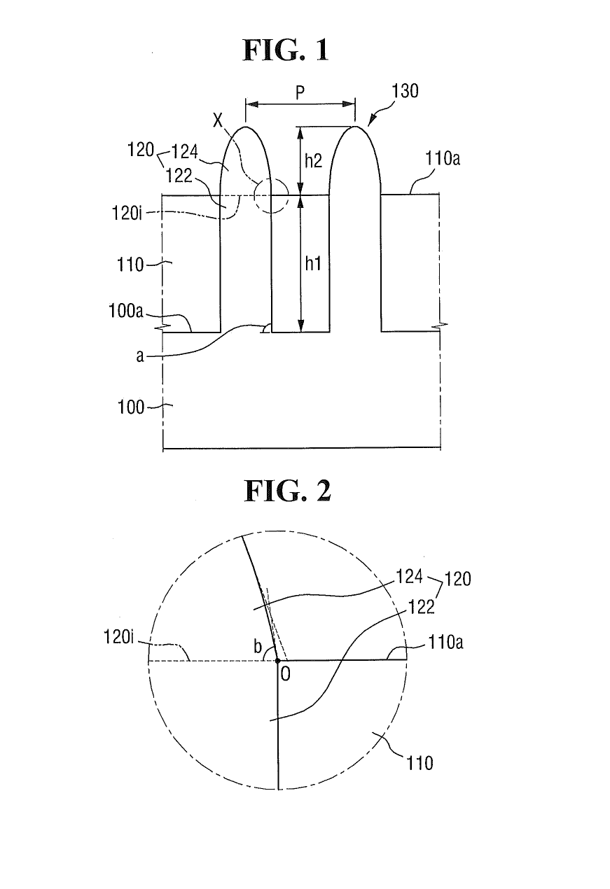

Hereinafter, a semiconductor device according to an embodiment of the present invention will be described with reference to FIGS. 1 and 2.

FIG. 1 is a view explaining a semiconductor device according to an embodiment of the present invention, and FIG. 2 is an enlarged view of a portion X in FIG. 1.

Referring to FIG. 1, a semiconductor device may include a substrate 100, a first fin 120, and an isolation film 110.

Specifically, the substrate 100 may be, for example, a bulk silicon or SOI (Silicon-On-Insulator). The substrate 100 may be a silicon substrate, or may include another material, for example, such as silicon germanium, indium antimonide, lead telluride, indium arsenide, indium phosphide, gallium arsenide, or gallium antimonide. On the other hand, the substrate 100 may be provided by forming an epitaxial layer on a base substrate.

The first fin 120 may be extended long along one direction. The first fin 120 may be a part of the substrate 100, or may include an epitaxial layer grown from the substrate 100. The first fin 120 may include a first region 122, a second region 124, and a boundary line 120i, which are divided on the basis of the isolation layer 110. The boundary line 120i of the first fin 120 may be located between the first region 122 and the second region 124, and specifically, may be a boundary surface between the first region 122 and the second region 124. The positional relations between the first fin 120 and the isolation film 110 will be described later.

The isolation film 110 may be formed on the substrate 100. The isolation film 110 may be formed to be in contact with a part of the first fin 120. Specifically, the isolation film 110 may be formed to be in contact with the first region 122 of the first fin 120 and to be in non-contact with the second region 124 of the first fin 120 on the substrate 100. The isolation film 110 may include, for example, at least one of a silicon oxide film, a silicon nitride film, and a silicon oxynitride film.

Referring to FIGS. 1 and 2, the first region 122 of the first fin 120 may have a first slope a. The first slope a may be an angle formed between a side surface of the first region 122 and an extended line of an upper surface 100a of the substrate 100, and may be, for example, at right angles. In other words, the first region 122 of the first fin 120 may have a slope that is at right angles to the boundary line 120i. Here, the term “at right angles” means not only accurately at 90 degrees but also inclined due to an error in a fabricating process. In an embodiment of the present invention, if the first slope a is in the range of 87 to 90 degrees, it is considered to be at right angles.

Referring to FIGS. 1 and 2, the second region 124 of the first fin 120 may have a slope at an acute angle with respect to the boundary line 120i. Here, “the second region has an acute angle” means that an angle formed between a tangent line drawn from a certain point and the boundary line 120i is an acute angle. According to an embodiment of the present invention, the “acute angle” means an angle that is smaller than 87 degrees.

A point where the first fin 120 and the isolation film 110 meet each other may be a boundary point 0. The boundary point 0 is a point on the boundary line 120i that is located between the first region 122 and the second region 124. On the boundary line 120i, the acute angle that the second region 124 has may be a second slope b. The second slope b may have, for example, a value in the range of 79 to 87 degrees. Specifically, the angle formed between the tangent line drawn at the boundary point 0 and the boundary line 120i becomes the second slope b. The second slope b is an acute angle and has, for example, an angle in the range of 79 to 87 degrees.

In an embodiment of the present invention, the boundary line 120i and the upper surface 110a of the isolation film are put on the same plane. That is, the extended line of the boundary line 120i is located on the upper surface 110a of the isolation film.

Referring to FIGS. 1 and 2, the angle formed between the second region 124 of the first fin 120 and the boundary line 120i may be changed. That is, the slope, which is the acute angle that the second region 124 has with respect to the boundary line 120i, may be changed.

For example, the slope which is the acute angle that the second region 124 has with respect to the boundary line 120i may be smaller as the second region 124 becomes more distant from the boundary line 120i. At a point that is most distant from the boundary line 120i, the slope which is the acute angle that the second region 124 has may be 0 degrees. That is, at the point that is most distant from the boundary line 120i, the tangent line of the second region 124 may be substantially in parallel to the boundary line 120i. Here, “being parallel” may mean not only the same distance between two certain points but also inclusion of a minute difference in distance that may occur due to an error in a fabricating process. The second region 124 of the first fin 120 may be of a cone type, and specifically, of a cone type with a rounded tip portion.

For example, the slope, which is the acute angle that the second region 124 has, includes the second slope b that is constant from the boundary line 120i to a predetermined height, and thereafter, the slope becomes smaller as it is more distant from the boundary line 120i. That is, the surface of the second region 124 may be composed of a combination of a plane and a curved surface. The surface of the second region until the portion that has the second slope b may be a plane, and the surface of the second region 124 thereafter may be curved surface.

Referring to FIG. 1, the height of the first region 122 of the first fin 120 is a first height h1, and the height of the second region 124 of the first fin 120 may be a second height h2. The first height h1 is equal to the height of the isolation film 110.

The first height h1 of the first region 122 may be higher than the second height h2 of the second region 124. The ratio of the first height h1 of the first region 122 to the second height h2 of the second region 124 may be 2 to 10, but is not limited thereto. In some embodiments of the present invention, it is assumed that the first height h1 of the first region 122 is twice the second height h2 of the second region 124.

Referring to FIG. 1, the semiconductor device may further include a second fin 130. The second fin 130 may project from the substrate 100 and may be formed adjacent to the first fin 120. The explanation of the second fin 130 will be omitted since it is duplicate to the explanation of the first fin 120.

The distance between the first fin 120 and the second fin 130 is called a pitch P. Here, the “pitch” is an interval between adjacent fins, and specifically, means a distance between centers of the adjacent fins. In an embodiment of the present invention, the pitch P means a distance between the width center of the first region of the first fin 120 and the width center of the first region of the second fin 130.

The ratio of the height (h1+h2) of the first fin 120 to the pitch between the first fin 120 and the second fin 130 may be, for example, in the range of 0.6 to 1.2. In an embodiment of the present invention, since the ratio of the first height h1 of the first region 122 to the second height h2 of the second region 124 may be in the range of 2 to 10, the pitch P between the first fin 120 and the second fin 130 may be smaller than the first height h1 of the first region 122 of the first fin 120.

In an embodiment of the present invention, the pitch P between the first fin 120 and the second fin 130 may be, for example, equal to or smaller than 48 nm.

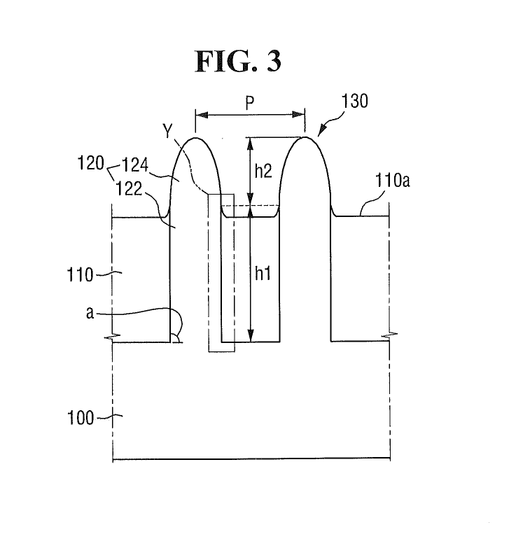

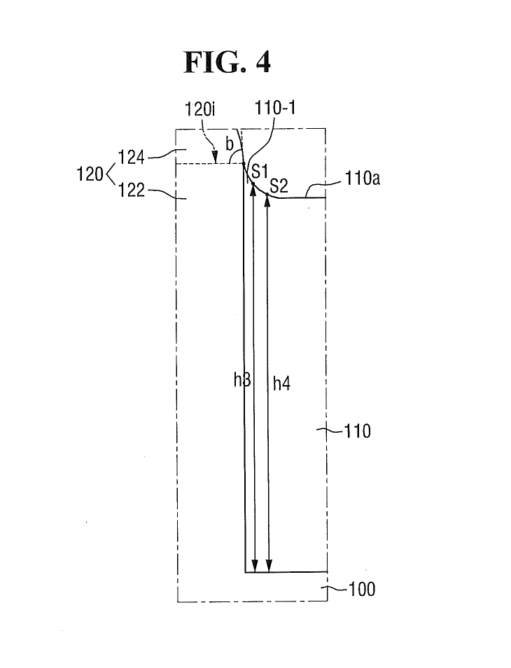

FIGS. 3 and 4 are views explaining a semiconductor device according to another embodiment of the present invention. The same reference numerals are used for portions that may be duplicate to those in the above-described embodiment, and the explanation thereof will be simplified or omitted.

FIG. 3 is a view explaining a semiconductor device according to another embodiment of the present invention, and FIG. 4 is an enlarged view of a portion Y in FIG. 3.

Referring to FIG. 3, the semiconductor device may include a substrate 100, a first fin 120, and an isolation film 110.

The first fin 120, which includes a first region 122, a second region 124, and a boundary line 120i, may be formed to project from the substrate 100. The isolation film 110, which is formed to be in contact with a part of the first fin 120, may be formed to be in contact with the first region 122 of the first fin 120, and may be formed to be in non-contact with the second region 124 of the first fin 120.

The isolation film 110, which is in contact with both sides of the first fin 120, may project further than the isolation film 110 that is located between the first fin 120 and the second fin 130. In other words, an upper surface 110a of the isolation film 110 may not be put on the same plane, and for example, may not be put on a plane that is parallel to the upper surface 100a of the substrate.

Since the first region 122 of the first fin 120 is formed to be in contact with the isolation film 110, a first height h1 of the first region 122 of the first fin 120 becomes a distance from the upper surface 100a of the substrate 100 to the projecting isolation film 110. A second height h2 of the second region 124 of the first fin 120 becomes a distance from the projecting isolation film 110 to a tip portion of the second region 124.

Referring to FIGS. 3 and 4, the upper surface 110a of the isolation film 110 may include a first point S1 and a second point S2. The first point S1 is closer to the first fin 120 than the second point S2. A distance from the upper surface 100a of the substrate 100 to the first point S1 may be a third height h3, and a distance from the upper surface 100a of the substrate to the second point S2 may be a fourth height h4.

The third height h3 of the first point S1 and the fourth height h4 of the second point S2 may have different values from each other. For example, since the upper surface 110a of the isolation film 110 may project as it is adjacent to the first fin 120, the third height h3 of the first point S1 may be higher than the fourth height h4 of the second point S2.

Referring to FIGS. 3 and 4, the isolation film 110 may include a projection portion 110-1 provided in a portion where the first fin 120 and the second fin 130 come in contact with each other. That is, on the isolation film 110, the portion where the first fin 120 and the second fin 130 come in contact with each other may project, and a middle portion of the first fin 120 and the second fin 130 may be a plane. However, such a shape of the isolation film 110 is merely to explain an embodiment of the present invention, but is not limited thereto. That is, if the first fin 120 and the second fin 130 are sufficiently spaced apart from each other to form a pitch P, the upper surface 110a of the isolation film 110 may include a plane between the first fin 120 and the second fin 130. However, if the pitch P between the first fin 120 and the second fin 130 is small, the isolation film 110 between the first fin 120 and the second fin 130 may include the projection portion 110-1 only. The projection portion 110-1 may be formed to be in contact with both sides of the first region 122 of the first fin 120.

If the upper surface 110a of the isolation film includes a plane in the middle portion of the first fin 120 and the second fin 130, the upper surface of the isolation film that is a plane is further adjacent to the substrate 100 than the boundary line 120i.

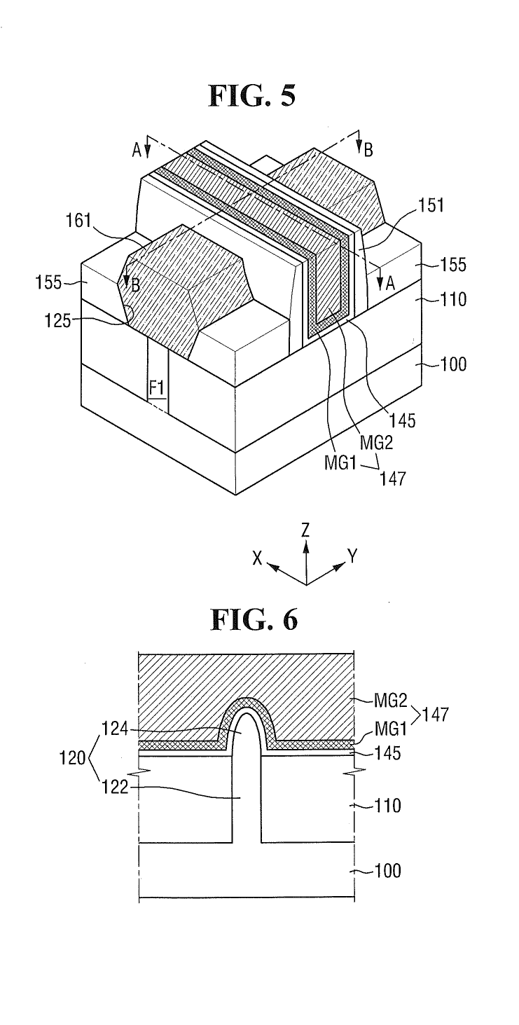

Referring to FIGS. 5 to 7, a semiconductor device according to still another embodiment of the present invention will be described. Since this embodiment is related to a fin type transistor including the fin as described above with reference to FIG. 1, the same reference numerals are used for the same portions that may be duplicate to those in the above-described embodiment, and the explanation thereof will be simplified or omitted.

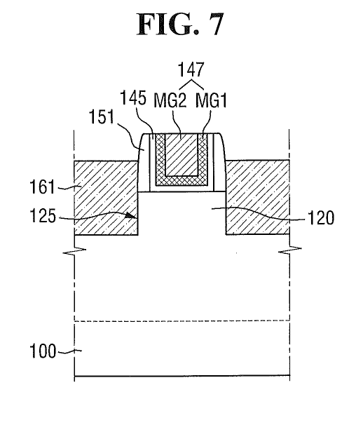

FIG. 5 is a view explaining a semiconductor device according to still another embodiment of the present invention, FIG. 6 is a cross-sectional view taken along line AA in FIG. 5, and FIG. 7 is a cross-sectional view taken along line BB in FIG. 5.

Referring to FIGS. 5 to 7, the semiconductor device may include a first fin F1, a gate electrode 147, a recess 125, and a source/drain 161.

The first fin 120 may be extended long along a second direction Y1. The first fin 120 may be a part of the substrate 100, or may include an epitaxial layer grown from the substrate 101. The isolation film 110 may cover a side surface of the first fin 120.

The gate electrode 147 may be formed on the first fin 120 to cross a second region 124 of the first fin 120. The gate electrode 147 may be extended in a first direction X1.

The gate electrode 147 may include metal layers MG1 and MG2. As illustrated, the gate electrode 147 may include two or more laminated metal layers MG1 and MG2. The first metal layer MG1 serves to adjust a work function, and the second metal layer MG2 serves to fill a space formed by the first metal layer MG1. For example, the first metal layer MG1 may include at least one of TiN, TaN, Tic, and TaC. Further, the second metal layer MG2 may include W or Al. Further, the gate electrode 147 may be made of Si or SiGe that is not metal. The gate electrode 147 may be formed, for example, through a replacement process, but is not limited thereto.

A gate insulating film 145 may be formed between the first fin 120 and the gate electrode 147. As illustrated in FIG. 6, the gate insulating film 145 may be formed on an upper portion of the second region 124 of the first fin 120, Further, the gate insulating film 145 may be disposed between the gate electrode 147 and the isolation film 110, The gate insulating film 145 may include a high-k material having higher dielectric constant than a silicon oxide film, For example, the gate insulating film 145 may include HfO2, ZrO2, or Ta2O5.

The recess 125 may be formed in the first fin 120 on both sides of the gate electrode 147. The side wall of the recess 125 has a slope, and the recess 125 is shaped to become wider as it becomes more distant from the substrate 100. The width of the recess 125 may be wider than the width of the first fin 120.

The source/drain 161 is formed in the recess 125. The source/drain 161 may be in the form of an elevated source/drain. That is, an upper surface of the source/drain 161 may be higher than a lower surface of an interlayer insulating film 155. Further, the source/drain 161 and the gate electrode 147 may be insulated from each other by a spacer 151.

If the semiconductor device is a PMOS fin type transistor, the source/drain 161 may include a compressive strength material. For example, the compressive stress material may be a material having higher lattice constant than Si, and for example, may be SiGe. By applying compressive stress to the first fin 120 that includes the compressive stress material, mobility of holes that are carriers of a channel region can be improved.

Alternatively, if the semiconductor device is an NMOS fin type transistor, the source/drain 161 may be made of the same material as the substrate 100 or a tensile stress material. For example, in the case where the substrate 100 is made of Si, the source/drain 161 may be made of Si, or a material having lower lattice constant than Si (for example, SiC).

The spacer 151 may include at least one of a nitride film and an oxynitride film.

Referring to FIGS. 5 to 23, a method for fabricating a semiconductor device according to an embodiment of the present invention will be described.

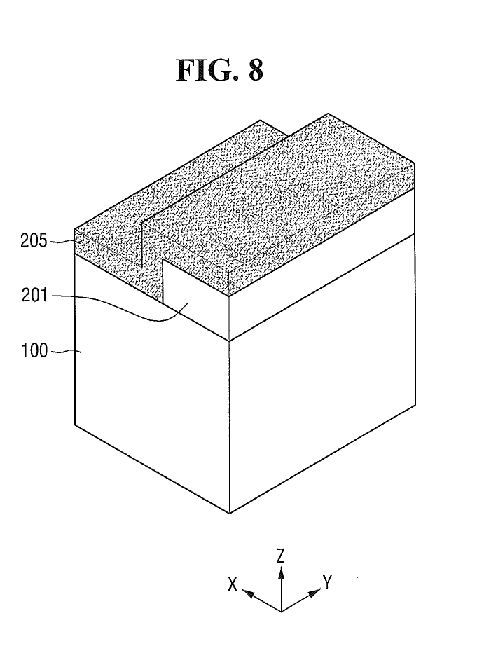

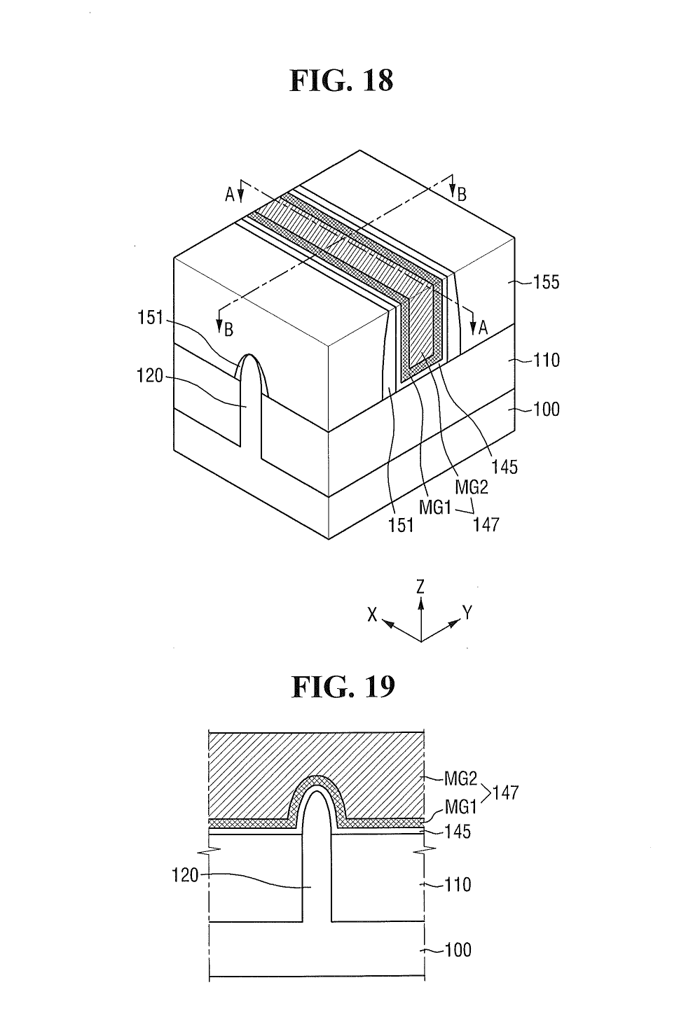

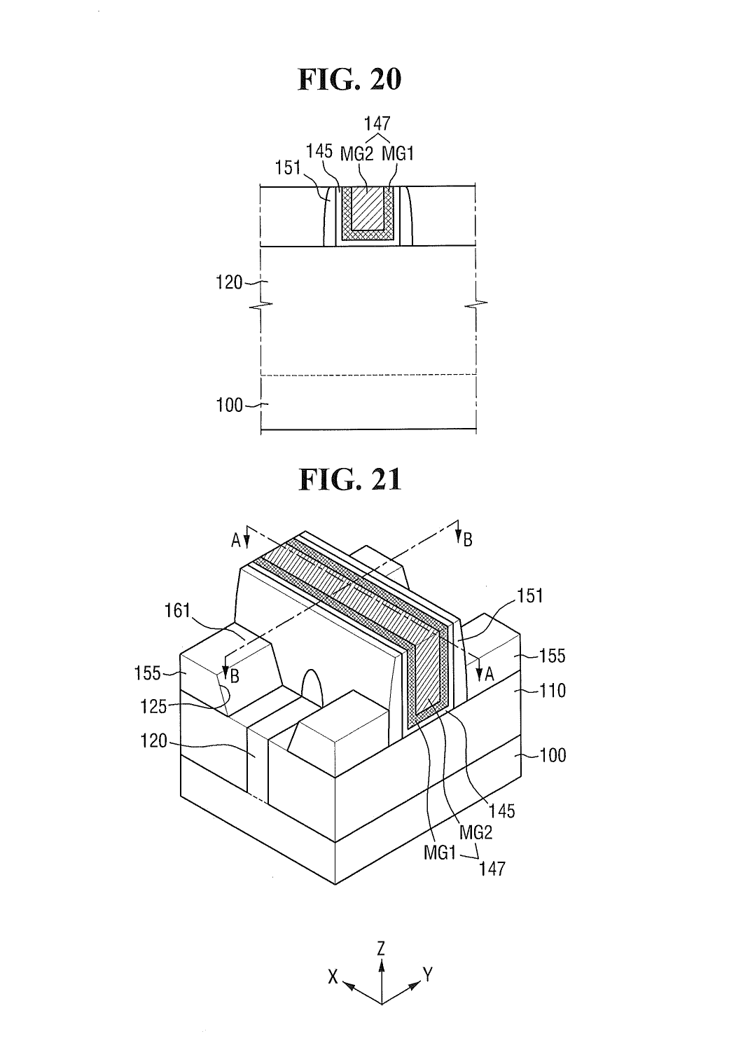

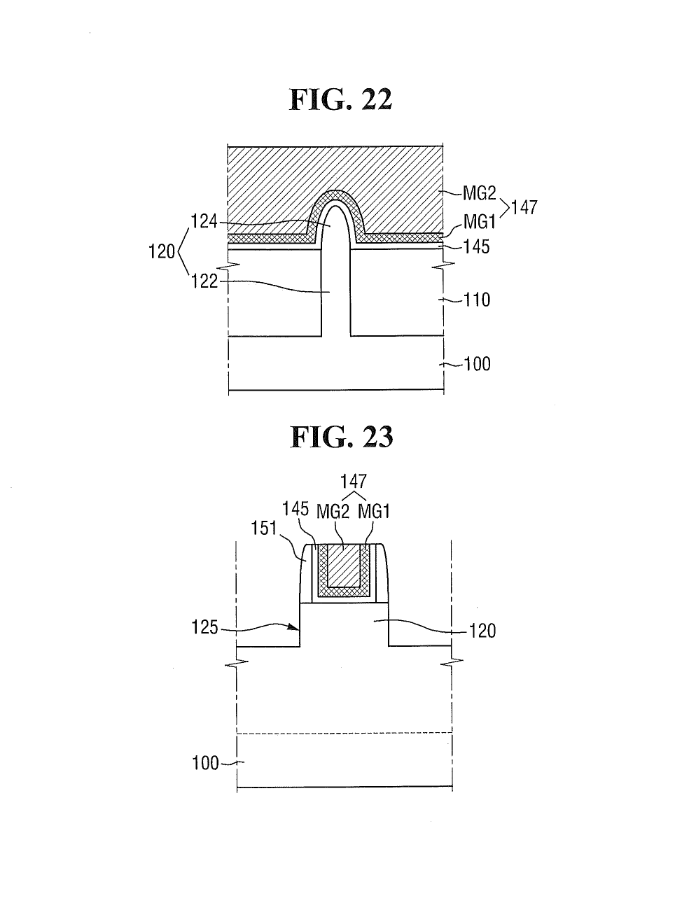

FIGS. 8 to 23 are views explaining intermediate steps of a method for fabricating a semiconductor device according to an embodiment of the present invention. FIG. 19 is a cross-sectional view taken along line A-A in FIG. 18, and FIG. 20 is a cross-sectional view taken along line B-B in FIG. 18. FIG. 22 is a cross-sectional view taken along line A-A in FIG. 21, and FIG. 23 is a cross-sectional view taken along line B-B in FIG. 21.

Referring to FIG. 8, a first mask pattern 201 may be formed on the substrate 100. A second mask film 205 may be formed on the substrate 100 on which the first mask pattern 201 is formed. The second mask film 205 may be substantially conformally formed on the upper surface of the substrate 100 on which the first mask pattern 201 is formed. The first mask pattern 201 and the second mask film 205 may include materials having etching selectivity to each other. For example, the second mask film 205 may include at least one of silicon oxide, silicon nitride, silicon oxynitride, metal film, photoresist, SOG (Spin On Glass) and/or SOH (Spin On Hard mask). The first mask pattern 201 may be formed of a material, which is different from a material of the second mask film 205, among the above-described materials. The first mask pattern 201 and the second mask film 205 may be formed by at least one of a PVD (Physical Vapor Deposition process), a CVD (Chemical Vapor Deposition process), an ALD (Atomic Layer Deposition process), and a spin coating method.

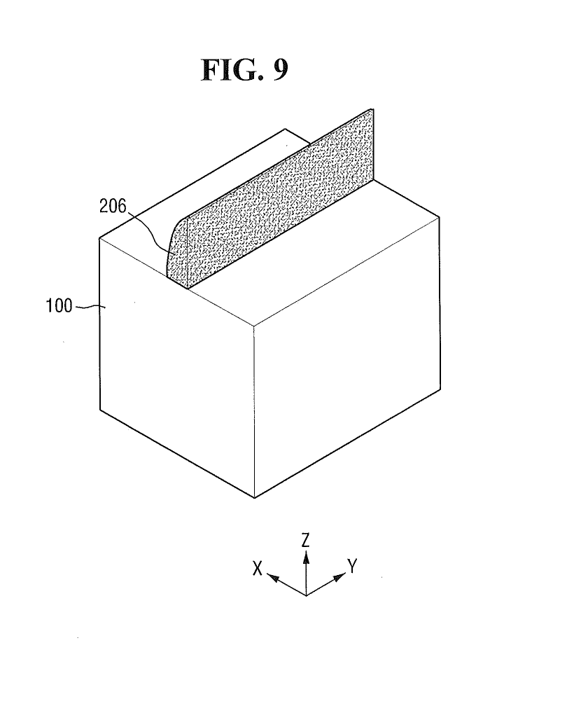

Referring to FIG. 9, a second mask pattern 206 may be formed from the second mask film 205 by an etching process. The second mask pattern 206 may be in the form of a spacer that exposes the first mask pattern 201. By removing the first mask pattern 201 that is exposed by the second mask pattern 206, the substrate 100 on both sides of the second mask pattern 206 may be exposed. The removal of the first mask pattern 201 may minimize the etching of the second mask pattern 206, and may include a selective etching process that can remove the first mask pattern 201.

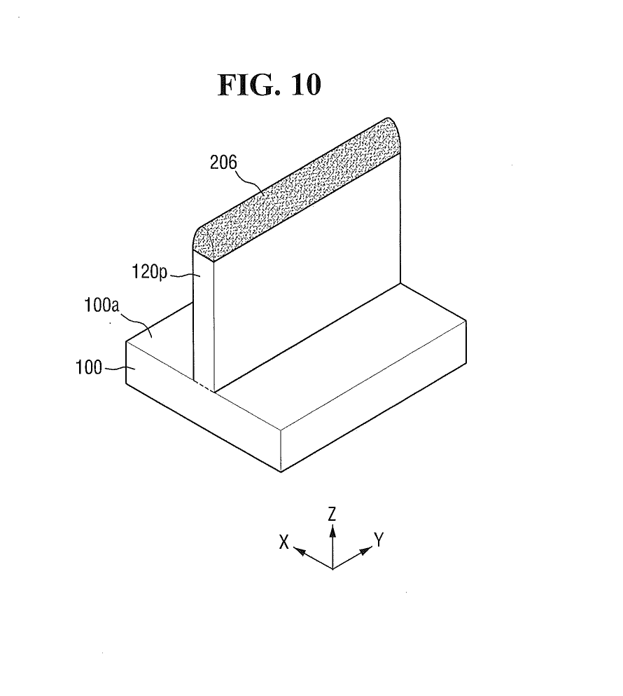

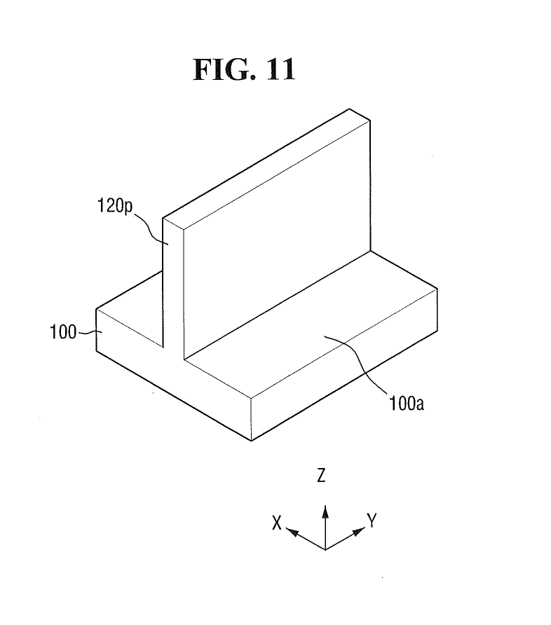

Referring to FIGS. 10 and 11, the substrate 100 is etched using the second mask pattern 206 as an etching mask. By etching a part of the substrate 100, a dummy fin 120p may be formed on the substrate 100. The second mask pattern 206 may remain on the dummy fin 120p. By removing the second mask pattern 206 that remains on the dummy fin 120p, the dummy fin 120 that projects from the substrate 100 may be formed.

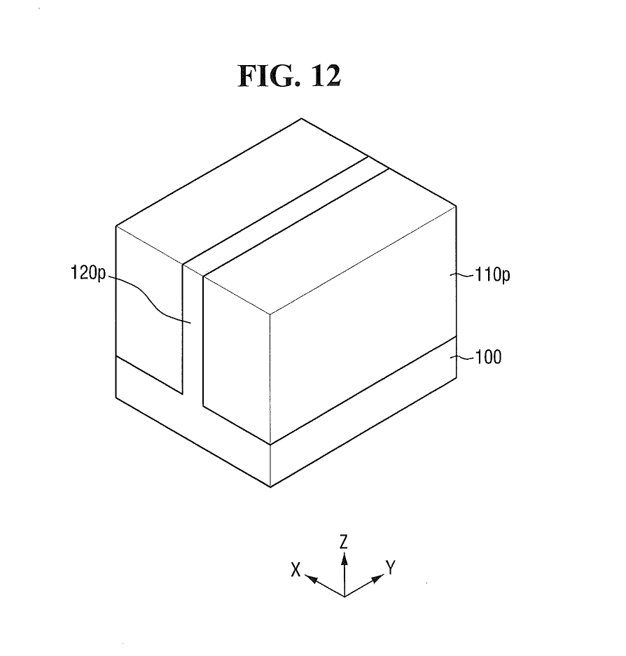

In an embodiment of the present invention, it is described that the second mask pattern 206 on the dummy fin 120p is removed before a pre-isolation film 110p (in FIG. 12) that surrounds the dummy fin 120p is formed. However, the present invention is not limited thereto, and the second mask pattern 206 may be removed through a planarization process after the pre-isolation film is formed on the dummy fin 120p on which the second mask pattern 206 remains.

The dummy fin 120p may have a slope that is at right angles. Specifically, an angle between the side surface of the dummy fin 120p and the upper surface 100a of the substrate 100 may be at right angles. In the same manner as the second mask pattern 206, the dummy fin 120p may be formed to extend in a second direction Y.

Referring to FIG. 12, the pre-isolation film 110p is formed on the substrate 100. The pre-isolation film 110p surrounds the circumference of the dummy fin 120p, and exposes the upper surface of the dummy fin 120p. The pre-isolation separation film 110p may be formed of a material including at least one of a silicon oxide film, a silicon nitride film, and a silicon oxynitride film.

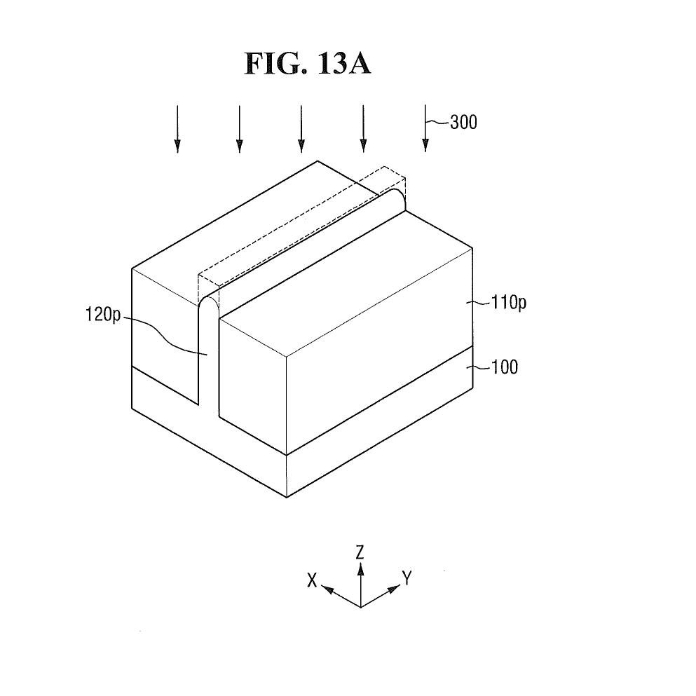

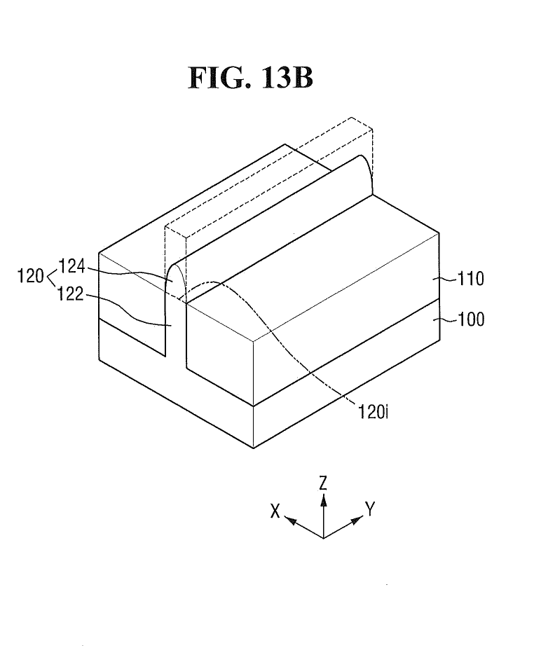

Referring to FIGS. 13A and 13B, the pre-isolation film 110p and the dummy fin 120p may be etched by an etching process 300. Through this, the first fin 120 and the isolation film 110 maybe formed on the substrate 100. The first fin 120 includes a first region 122 having a slope that is at right angles, a second region 124 having an acute angle, and a boundary line 120i between the first region 122 and the second region 124. The isolation film 110 is formed to be in contact with the first region 122, and is formed to be in non-contact with the second region 124.

The etching process 300 to etch the pre-isolation film 110p and the dummy fin 120p may include, for example, a dry etching process. In an embodiment of the present invention, it is assumed that the etching process 300 is the dry etching process. In an embodiment, the horizontal etching selectivity relative to the vertical etching selectivity of etching process 300 may be greater than the horizontal etching selectivity relative to the vertical etching selectivity of the etching process to form dummy fin 120.

The heights of the pre-isolation film 110p and the dummy fin 120p is gradually decreased by the etching process 300, and thus the first fin 120 and the isolation film 110 may be formed simultaneously. Specifically, since the materials included in the dummy fin 120p and the pre-isolation film 110p are different from each other, the etching selectivity of etching gases of the dummy fin 10p and the pre-isolation film 110p may differ from each other. Accordingly, the first fin 120 may be formed to project from the isolation film 110.

Since the second region 124 of the first fin 120 is a region that is formed by the etching process 300, the second region is an etched region. However, since the first region 122 of the first fin 120 is a region surrounded by the isolation film 110, but is not a region that is etched by the etching process 300, the first region 122 is a region that is non-etched by the etching process 300.

The second region 124 that is a region formed by the etching process has a slope that is an acute angle with respect to the boundary line 120i. The slope of the acute angle that the second region 124 has on the boundary line 120i may be in the range of 79 to 87 degrees. The slope of the acute angle that the second region 124 has on the boundary line 120i may be changed depending on the kinds of etching gases used in the etching process 300.

If the height of the first region 122 is approximately twice the height of the second region 124, the first fin 120 and the isolation film 110 may be formed by etching the dummy fin 120p and the pre-isolation film 110p until a half of the pre-isolation film 110p is removed by the etching process 300.

Further, doping for adjusting a threshold voltage may be performed on the first fin 120. If the semiconductor device is an NMOS fin type transistor, the impurity may be boron (B). If the semiconductor device is a PMOS fin type transistor, the impurity may be phosphorous (P) or arsenide (As).

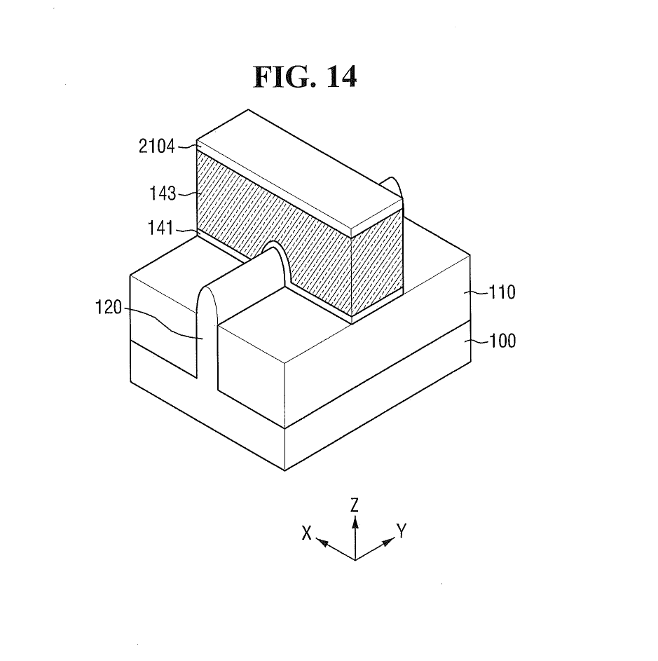

Referring to FIG. 14, by performing the etching process using a third mask 2104, a dummy gate insulating film 141, which crosses the first fin 120 and is extended in the first direction X, and a dummy gate electrode 143 are formed.

For example, the dummy gate insulating film 141 may be a silicon oxide film, and the dummy gate electrode 143 may be made of poly silicon.

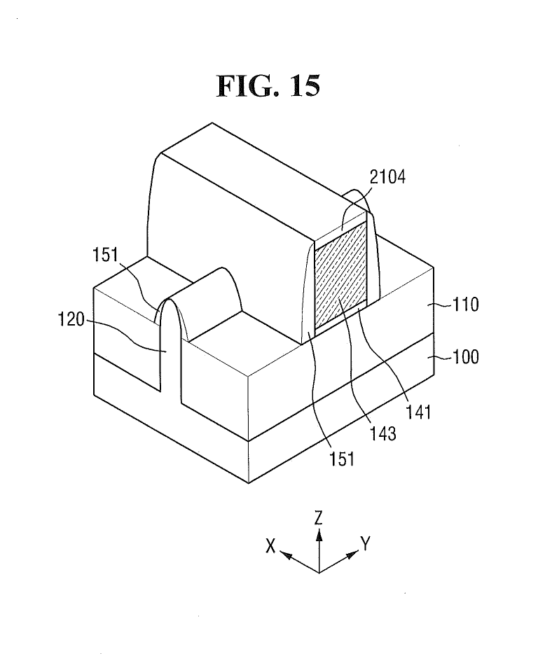

Referring to FIG. 15, a first spacer 151 is formed on a side wall of the dummy gate electrode 143 and a side wall of the first fin 120.

For example, the first spacer 151 may be formed by performing an etch-back process after forming an insulating film on the resultant material on which the dummy gate electrode 143 is formed. The first spacer 151 may expose the upper surface of the third mask pattern 2104 and the upper surface of the first fin 120. The first spacer 151 may be a silicon nitride film or a silicon oxynitride film.

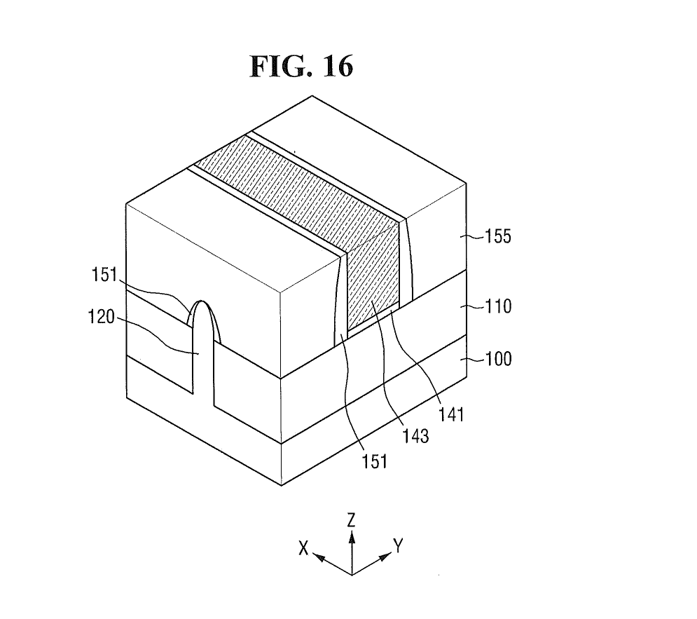

Referring to FIG. 16, the interlayer insulating film 155 is formed on the resultant material on which the first spacer 151 is formed. The interlayer insulating film 155 may be, for example, a silicon oxide film.

Then, the interlayer insulating film 155 is planarized until the upper surface of the dummy gate electrode 143 is exposed. As a result, the third mask pattern 2104 is removed, and the upper surface of the dummy gate electrode 143 may be exposed.

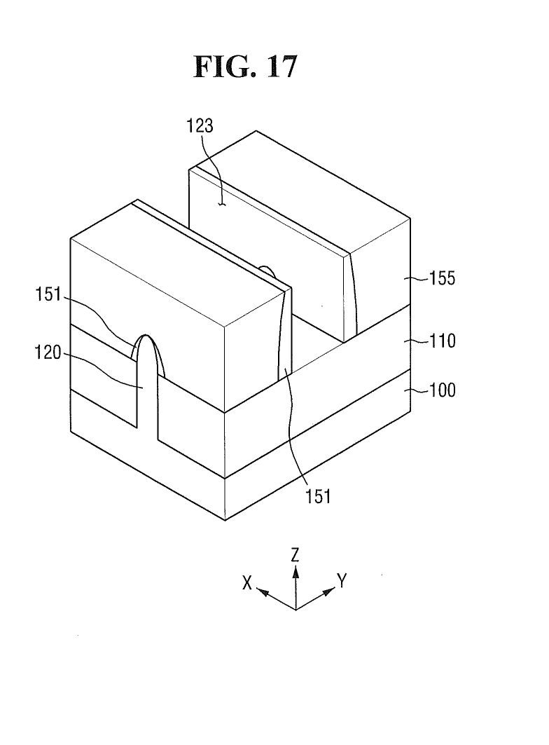

Referring to FIG. 17, the dummy gate insulating film 141 and the dummy gate electrode 143 are removed. As the dummy gate insulating film 141 and the dummy gate electrode 143 are removed, a trench to expose the isolation film 110 is formed.

Referring to FIGS. 18 to 20, a gate insulating film 145 and the gate electrode 147 are formed in the trench 123.

The gate insulating film 145 may be substantially conformally formed along a side wall and a lower surface of the trench 123. The gate electrode 147 including metal layers MGI and MG2 may be formed on the gate insulating film 145.

Referring to FIGS. 21 to 23, a recess 125 is formed in the first fin 120 on both sides of the gate electrode 147.

The recess 125 may be formed in the fin F1 on both sides of the gate electrode 147.

The side wall of the recess 125 has a slope, and the recess 125 is shaped to become wider as it becomes more distant from the substrate 100.

Referring to FIGS. 5 to 7, the source/drain 161 is formed in the recess 125. For example, the source/drain 161 may be in the form of an elevated source/drain in which the upper surface of the source/drain 161 is higher than the lower surface of the interlayer insulating film 155.

The source/drain 161 may be formed by an epitaxial process. Further, depending on whether the semiconductor device is a PMOS transistor or an NMOS transistor, the materials of the source/drain may differ. Further, if needed, impurities may be in-situ doped onto the source/drain 161 in the epitaxial process.

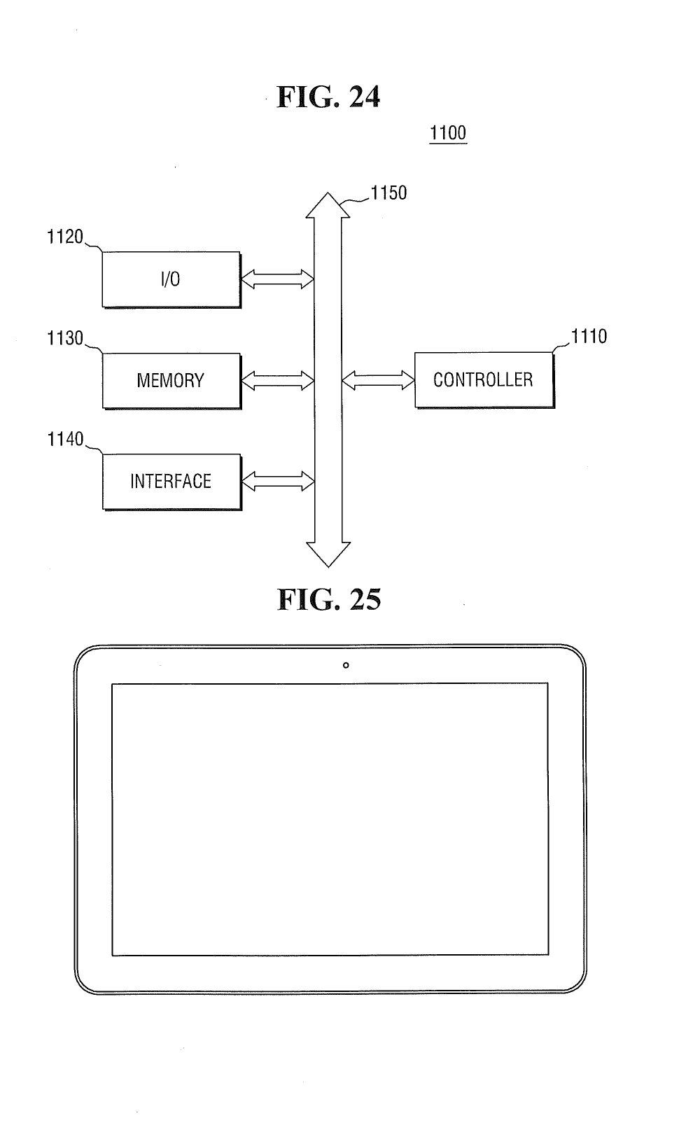

FIG. 24 is a block diagram of an electronic system including the semiconductor device according to some embodiments of the present invention.

Referring to FIG. 24, an electronic system 1100 according to an embodiment of the present invention may include a controller 1110, an input/output (I/O) device 1120, a memory device 1130, an interface 1140, and a bus 1150. The controller 1110, the I/O device 1120, the memory device 1130, and/or the interface 1140 may be coupled to one another through the bus 1150. The bus 1150 corresponds to paths through which data is transferred.

The controller 1110 may include at least one of a microprocessor, a digital signal processor, a microcontroller, and logic elements that can perform similar functions. The I/O device 1120 may include a keypad, a keyboard, and a display device. The memory device 1130 may store data and/or commands. The interface 1140 may function to transfer the data to a communication network or receive the data from the communication network. The interface 1140 may be of a wired or wireless type. For example, the interface 1140 may include an antenna or a wire/wireless transceiver. Although not illustrated, the electronic system 1100 may further include a high-speed DRAM and/or SRAM as an operating memory for improving the operation of the controller 1110. Fin thin film transistors according to embodiments of the present invention may be provided inside the memory device 1130 or may be provided as a part of the controller 1110 and the I/O device 1120.

The electronic system 1100 may be applied to a PDA (Personal Digital Assistant), a portable computer, a web tablet, a wireless phone, a mobile phone, a digital music player, a memory card, or all electronic devices that can transmit and/or receive information in wireless environments.

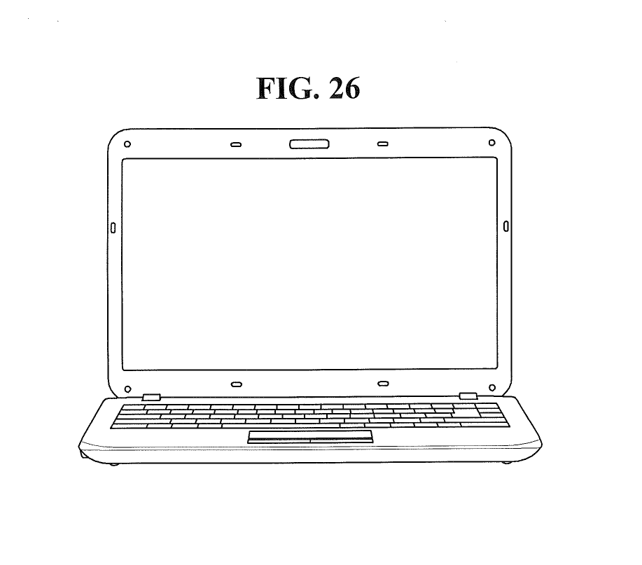

FIGS. 25 and 26 are exemplary views of a semiconductor system to which the semiconductor device according to some embodiments of the present invention can be applied. FIG. 25 illustrates a tablet PC, and FIG. 26 illustrates a notebook PC. At least one of the semiconductor devices according to the embodiments of the present invention can be applied to the tablet PC or the notebook PC. It is apparent to those of skilled in the art that the semiconductor devices according to some embodiments of the present invention can be applied even to other integrated circuit devices that have not been exemplified.

Although preferred embodiments of the present invention have been described for illustrative purposes, those skilled in the art will appreciate that various modifications, additions and substitutions are possible, without departing from the scope and spirit of the invention as disclosed in the accompanying claims.

What is claimed is:

1. A semiconductor device comprising:
a substrate;
a first fin formed on the substrate; and
an isolation film formed on the substrate and coming in contact with a part of the first fin,
wherein the first fin includes a first region that is in contact with the isolation film, a second region that is in non-contact with the isolation film, and a boundary line between the first region and the second region,
the first region has a slope that is at right angles with respect to the boundary line, and
the second region has a slope that is an acute angle with respect to the boundary line.

2. The semiconductor device of claim 1, wherein an upper surface of the isolation film comprises a first point that is closest to the first fin and a second point that is farther than the first point, and a first height from the substrate to the first point is different from a second height from the substrate tot the second point.

3. The semiconductor device of claim 2, wherein the first height is higher than the second height.

4. The semiconductor device of claim 1, wherein on the boundary line, the acute angle is in the range of 79 to 87 degrees.

5. The semiconductor device of claim 1, wherein the acute angle of the second region of the first fin is changed.

6. The semiconductor device of claim 5, wherein the acute angle becomes smaller as the second region becomes more distant from the boundary line.

7. The semiconductor device of claim 6, wherein the second region of the first fin is of a cone type.

8. The semiconductor device of claim 1, further comprising a second fin projecting from the substrate and adjacent to the first fin,
wherein a ratio of a height of the first fin to a pitch between the first fin and the second fin is 0.6 to 1.2.

9. The semiconductor device of claim 8, wherein the pitch is equal to or smaller than 48 nm.

10. The semiconductor device of claim 1, wherein a height of the first region is a first height, a height of the second region is a second height, and the first height is two times to 10 times the second height.

11. The semiconductor device of claim 1, further comprising a gate electrode that crosses the second region of the first fin, a recess formed in the first fin on both sides of the gate electrode, and a source/drain region formed in the recess.

12. A method for fabricating a semiconductor device comprising:
forming a dummy fin having a slope that is at right angles;
forming a pre-isolation film which surrounds a circumference of the dummy fin and exposes an upper surface of the dummy fin; and
forming a fin, which includes a first region having a slope that is at right angles, a second region having an acute angle, and a boundary line between the first region and the second region, by etching the dummy fin and the pre-isolation film, and forming an isolation film that is in contact with the first region.

13. The method for fabricating a semiconductor device of claim 12, wherein the fin and the isolation film are simultaneously formed.

14. The method for fabricating a semiconductor device of claim 12, wherein the etching to form the fin and the isolation film includes a dry etching process.

15. The method for fabricating a semiconductor device of claim 12, wherein the second region is an etched region, and the first region is a non-etched region.

16. The method for fabricating a semiconductor device of claim 12, wherein the forming the fin and the isolation film comprises etching the dummy fin and the pre-isolation film until a half of the pre-isolation film is removed.

17. A method for fabricating a semiconductor device comprising:
etching a substrate with a first etchant and a fin mask pattern to form a fin extending in a vertical direction on the substrate;
removing the fin mask pattern;
forming a pre-isolation film that surrounds the fin and exposes an upper surface of the fin;
simultaneously etching the pre-isolation film and the fin with a second etchant to form an isolation film in contact with a lower portion of the fin and expose a curved upper portion of the fin, wherein a horizontal etch rate of the fin with the second etchant is greater than a horizontal etch rate of the fin with the first etchant.

18. The method for fabricating a semiconductor device of claim 17, wherein a ratio of a height of the lower portion of the fin to a height of the upper portion of the fin is 2 to 10.

19. The method for fabricating a semiconductor device of claim 18, further comprising:
forming an adjacent fin, wherein a pitch distance from the center of the fin to the center of the adjacent fin is less than the height of the lower portion of the fin.

20. The method for fabricating a semiconductor device of claim 19, wherein the ratio of a sum of the height of the lower portion and the height of the upper portion to the pitch distance is 0.6 to 1.2.
